(19) United States
(12) Patent Application Publication
(10) Pub. No.: US 2013/0042802 A1
(43) Pub. Date: Feb. 21, 2013

(54) METHOD OF PRODUCTION OF SIC SINGLE CRYSTAL

(71) Applicants: Katsunori Danno, Susono-shi (JP); Akinori Seki, Sunto-gun (JP); Hiroaki Saitoh, Mishima-shi (JP); Kawai Yoichiro, Okazaki-shi (JP)

(72) Inventors: Katsunori Danno, Susono-shi (JP); Akinori Seki, Sunto-gun (JP); Hiroaki Saitoh, Mishima-shi (JP); Kawai Yoichiro, Okazaki-shi (JP)

(21) Appl. No.: 13/383,265

(22) PCT Filed: Jul. 17, 2009
(86) PCT No.: PCT/JP2009/063306

§ 371 Date: Jan. 10, 2012

(51) Int. Cl. C30B 19/08

(52) U.S. Cl. 117/60

(57) ABSTRACT

The present invention provides a method of production of SiC single crystal using the solution method which prevents the formation of defects due to causing a seed crystal to touch the melt for seed touch, and thereby causes growth of an Si single crystal reduced in defect density. The method of the present invention is a method of production of an SiC single crystal which causes an SiC seed crystal to touch a melt containing Si in a graphite crucible to thereby cause growth of the SiC single crystal on the SiC seed crystal, characterized by making the SiC seed crystal touch the melt in the state where the C is not yet saturated.

### TECHNICAL FIELD

The present invention relates to a method of production of an SiC single crystal by the solution method.

### BACKGROUND ART

SiC has a larger energy band gap compared with Si, so various techniques for production of high quality SiC single crystal suitable for semiconductor materials have been proposed. As the method of production of SiC single crystal, up to now, various diverse methods have been tried out, but the sublimation method and the solution method are currently the most general. The sublimation method is fast in growth rate, but has the disadvantage that micropipes and other defects and transformation of the crystal polytype easily occur. Opposed to this, while the growth rate is relatively slow, these defects are not present in the solution method. This method is therefore considered promising.

The method of production of SiC single crystal by the solution method maintains a temperature gradient inside the Si melt in the graphite crucible where the temperature falls from the inside toward the melt surface. At the bottom high temperature part, the C which dissolves from the graphite crucible into the Si melt mainly rides the convection of the melt to rise and reach the low temperature part near the melt surface and become supersaturated there. If causing an Si seed crystal which is held at the tip of a graphite rod to touch the melt surface, the supersaturated C crystallizes on the SiC seed crystal by epitaxial growth as an SiC single crystal. In the present application, the “growth temperature”, “touch temperature”, etc. mean the temperature at the melt surface.

An SiC single crystal, in particular for securing good device characteristics as a semiconductor material, has to have as low a density of dislocations and other lattice defects as possible. For this reason, it is important to make the single crystal grow so as to prevent the defect density of the seed crystal from being made to increase. If causing the seed crystal to touch the melt surface, the large temperature difference between the two will cause a large stress to be applied to the touch surface region of the seed crystal and the thin single crystal starting to grow, so lattice defects will occur. These will grow and lead to defects in the final single crystal.

Therefore, to prevent the occurrence of such defects, up to now, various proposals have been made regarding the method of making the seed crystal touch the melt.

Japanese Patent Publication (A) No. 2000-264790 proposes production of an SiC single crystal by the solution method comprising causing the seed crystal to touch the melt surface (seed touch) at the point of time of a growth temperature of ±100 to 150° C., allowing the melt to stand for a while until its temperature becomes the growth temperature, and causing the touch surface region of the seed crystal and/or the thin single crystal which has started to grow on the seed crystal to melt in the melt (meltback). However, if the concentration of C in the melt reaches a saturation concentration at the point of time of the seed touch, the SiC single crystal will start to grow immediately right after the seed touch and will become a heterogeneous polytype crystal, but crystal defects will occur. In the end, it is not possible to reliably prevent the occurrence of defects due to seed touch.

Further, the following proposals have been made.

Japanese Patent Publication (A) No. 7-172998 proposes to cause the seed crystal to descend to make it touch the melt surface at the point of time when the Si melt reaches a temperature lower than the growth temperature of 1700° C. by 100° C. and then make the temperature of the Si melt rise to the growth temperature to thereby cause the seed crystal surface to slightly melt and remove the work marks and oxide film present on the surface.

Japanese Patent Publication (A) No. 2007-261844 proposes to make an SiC single crystal grow by the solution method from a melt which contains Si, C, and Cr during which time causing the seed crystal to touch the melt after holding the melt for a predetermined time after the melt temperature reaches the growth temperature.

Japanese Patent Publication (A) No. 2006-143555 also makes a similar proposal.

In each case, it is not possible to reliably reduce defects caused by making the seed crystal touch the melt surface in the seed touch.

Further, Japanese Patent Publication (A) No. 2008-159740 proposes production of a SiC single crystal by the CVD method which comprises making a heating plate rise in temperature once up to a temperature region higher than the growth temperature before the start of SiC growth to clean the surface before growth, then causing the temperature to descend to the growth temperature to grow the SiC. In the CVD method, unlike the solution method, contamination of the heating plate surface is merely removed. This contributes nothing to the reduction of defects caused by the seed touch in the growth of the SiC single crystal by the solution method.

Further, Japanese Patent No. 3079256 proposes to use the sublimation method to grow an SiC single crystal during which time firing an energy beam (CO₂ gas laser beam) at the substrate or substrate holder so as to control the temperature inside the crystal during growth. This is also art for controlling the temperature profile in the crystal in the sublimation method—which is different from the solution method. It does not contribute anything to the reduction of defects due to the seed touch in the growth of SiC single crystal by the solution method.

### SUMMARY OF INVENTION

The present invention has as its object the provision of a method of production of SiC single crystal using the solution method which prevents the formation of defects due to causing a seed crystal to touch the melt for seed touch, and thereby causes growth of an Si single crystal reduced in defect density.

To achieve the above object, according to the present invention, there is provided a method of production of an SiC single crystal which causes an SiC seed crystal to touch a melt containing Si in a graphite crucible to thereby cause growth of the SiC single crystal on the SiC seed crystal, characterized by making the SiC seed crystal touch the melt in the state where the C is not yet saturated.

According to the method of the present invention, since the seed crystal is made to touch the melt in the state where the C is not yet saturated, the SiC single crystal will not start to grow immediately at the point of time of touch and it is possible to reliably prevent formation of defects. Even if defects are formed, they can be removed by meltback of the defect layer (seed crystal and initially grown single crystal layer) in the subsequent melt saturation process.

According to a preferable embodiment of the present invention, the touch operation is performed at a temperature less than the above temperature for causing growth and no temperature holding operation is performed at the touched state. By causing the seed touch at a temperature of less than the growth temperature, no crystal growth will occur at the time of touch. Further, since no temperature holding operation is performed at the touched state, it is possible to raise the temperature to the growth temperature without giving an extra margin of time for saturation of C.

According to another preferred embodiment of the present invention, an element for raising the solubility of C in the melt is added in the period from before touch to the start of growth. By raising the solubility of C in the melt, the saturation concentration of C rises, and even at the same C concentration, the ratio with respect to the saturation concentration falls, start of crystal growth at the time of seed touch becomes harder, and formation of defects can be more reliably prevented. The added elements for this are typically Cr and Ti. In addition, Al, Fe, Co, Ni, V, Zr, Mo, W, Ce, etc. may also be used.

When adding an element promoting the dissolution of C, a temperature holding operation may be performed if for not more than 60 minutes at the growth temperature before the seed touch. The above addition of an element causes the C saturation degree to fall, so a time delay occurs until C saturation at the growth temperature and formation of defects due to seed touch can be prevented.

### BRIEF DESCRIPTION OF DRAWINGS

FIG. 1 shows the basic structure of an SiC single crystal growth system using the solution method which is suitable for use of the method of the present invention.

FIGS. 2(1) to (9) show various states of coating a seed crystal.

FIGS. 3(1) to (2) show various states of attachment of small pieces to a seed crystal.

FIGS. 4(1) to (2) show various states of injecting ions into a seed crystal.

FIGS. 5(1) to (2) show various stages of formation of the tip of a seed crystal into a pointed or plateau shape.

FIG. 6 shows the relationship between temperature and amount of dissolution of C (ordinate) and time (abscissa) for explaining two modes A and B for keeping the amount of dissolution of C at the time of seed touch lower than the amount of dissolution of C at the time of growth.

FIG. 7 shows the relationship between the etch pit density of an SiC single crystal (ordinate) and seed touch temperature (abscissa) for the mode A.

FIG. 8 shows the relationship between the etch pit density of an SiC single crystal (ordinate) and seed touch temperature (abscissa) for the mode B.

### DESCRIPTION OF EMBODIMENTS

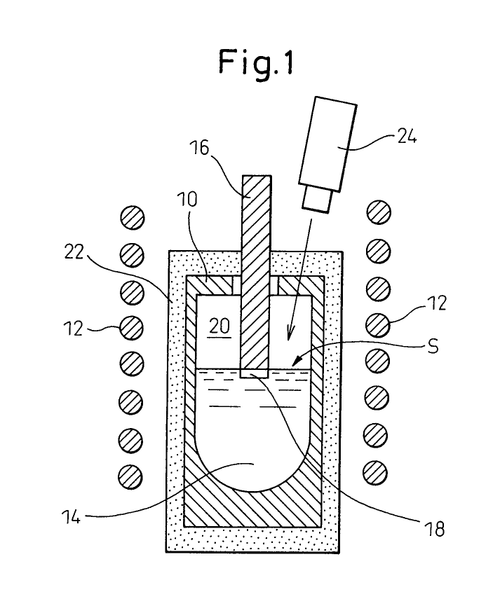

FIG. 1 shows the basic structure of a growth system of an SiC single crystal using the solution method which is suitable for use of the method of the present invention.

A graphite crucible 10 is surrounded by a high frequency heating coil 12. This is used to heat and melt feedstock inside of the crucible 10 to form a solution 14. From above that, an SiC seed crystal 18 which is supported at the bottom end of a graphite support rod 16 is made to descend to touch the surface S of the solution 14. An SiC single crystal is made to grow at the bottom surface of the SiC seed crystal 18 in an Ar gas or other inert atmosphere 20.

The graphite crucible 10 is covered in its entirety by a heat insulating material 22. The temperature of the surface S is measured by a radiant thermometer 24 by a noncontact method.

The radiant thermometer 24 can be set at an observation window above the solution surface where the surface S can be directly viewed. The temperature of the surface before and after the seed crystal 18 is made to touch the solution 14 can therefore be measured.

In general, Si is charged into the graphite crucible 10 as the feedstock of the Si melt and is heated by the high frequency heating coil 12 to form an Si melt. From the inside walls of the graphite crucible 10, C dissolves into this Si melt whereby an Si—C solution 14 is formed. In this way, the C source of the SiC is basically the graphite crucible 10, but it is also possible to supplementarily charge graphite blocks. Further, the crucible 10 may also be made of SiC. In that case, it is essential to charge graphite blocks as the C source.

Further, when adding elements for promoting dissolution of C into the melt (for example, Cr), first, as the melt feedstock, it is possible to charge Cr along with Si into the crucible 10 and heat to form the Si—Cr melt.

The method of the present invention is characterized by making the C concentration of the solution at the time of seed touch less than the C saturation concentration at the time of growth. That is, (1) the seed touch is performed at the point of time when the solution is not saturated with C so that the SiC single crystal does not form right after seed touch or (2) the seed touch is performed for a solution with a C concentration of an extent whereby crystal formed at the time of seed touch can be melted back in the subsequent saturation process of the solution.

As described in the requirement of the above (1), it is essential to separate the point of time of seed touch and the point of time of start of growth of the SiC single crystal. Due to this, it is possible to prevent the start of growth of the SiC single crystal immediately at the time of seed touch and possible to prevent the formation of defects due to seed touch.

The requirement of the above (2) will be further explained. At the time of seed touch, if a relatively low temperature seed crystal touches a high temperature solution, the solution temperature at the touched region will fall and locally a state of C saturation will result whereupon an SiC single crystal may slightly form. The amount of formation increases the larger the C supersaturation degree, so the seed touch is performed at a solution of a C concentration kept in a range of formation of an extent able to be removed by meltback.

Preferably, the seed touch is performed at a temperature lower than the growth temperature and the no temperature holding operation is performed in the state of seed touch. At the point of time of a temperature lower than the growth temperature, the C concentration in the solution is considerably lower than the C concentration at the growth temperature. If performing the seed touch at this point of time, the requirements of the above (1) and (2) are sufficiently saturated and, further, no temperature holding operation is performed in the state of seed touch. Due to this, the dissolution of C from the crucible is slower than the raising of the solution to the growth temperature in time relationship. Saturation by C will therefore not occur until the growth temperature. Due to this, in particular, achievement of the requirements (1) and (2) becomes more reliable.

More preferably, an element for promoting dissolution of C into the solution is charged into the solution in the period from before seed touch to the start of growth. Due to this, the saturated C concentration of the solution can be raised (C saturation degree can be lowered) and achievement of the requirements (1) and (2) become further easier. As the element for this, typically Cr and Ti are used, but in addition to these, it is also possible to use Al, Fe, Co, Ni, V, Zr, Mo, W, Ce, etc. Further, it is also possible to simply additionally charge Si.

When adding an element for promoting dissolution of C, it is possible to perform a temperature holding operation if for not more than 60 minutes at the growth temperature before the seed touch. The above addition of an element causes the C saturation degree to fall, so a time delay occurs until C saturation at the growth temperature and formation of defects due to seed touch can be prevented.

In the present invention, it is possible to apply the following modes to the seed crystal.

In one mode of the present invention, before the seed touch, it is also effective to heat the shaft which supports the seed crystal (graphite support rod) so as to preheat the seed crystal. This enables a local drop in the solution temperature due to the seed touch and the resultant occurrence of the problems explained above to be prevented.

In another mode, it is possible to fire a laser beam at the seed crystal before the seed touch so as to preheat the seed crystal. By directly heating the seed crystal rather than the support shaft, it is possible to more precisely control the preheating temperature of the seed crystal.

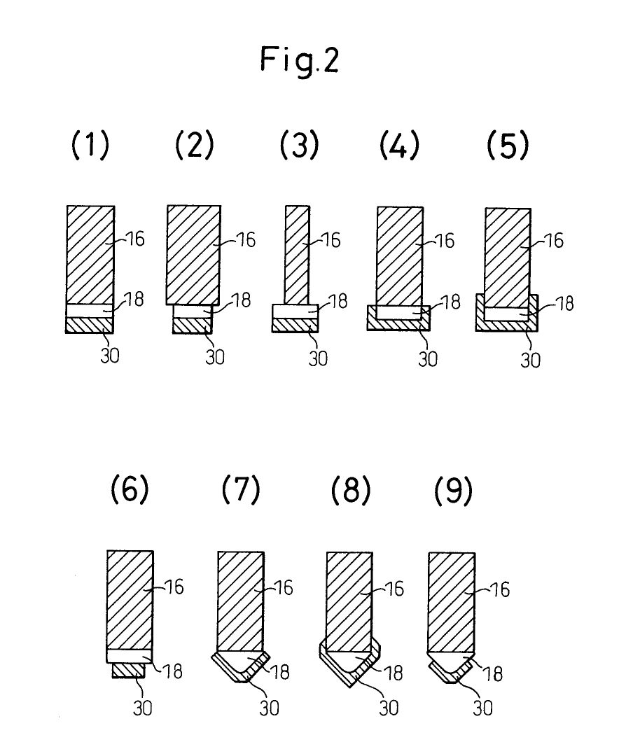

In another mode, as shown in FIGS. 2(1) to (9), it is possible to provide the seed crystal 18 with a protective coating 30. Reference numeral 16 represents the support shaft. For the coating 30, a metal, Si, C, or other material not detrimentally affecting the growth even if mixed into the solution is used. The surface coating melts and gives off heat at the time of the seed touch, due to which the heat shock at the time of seed touch can be eased. At the same time, it is possible to prevent abnormal growth due to vapor of the solution depositing on the surface of the SiC single crystal (formation of a polycrystal etc.) In particular, if selecting the coating material, an increase in the growth rate can also be expected.

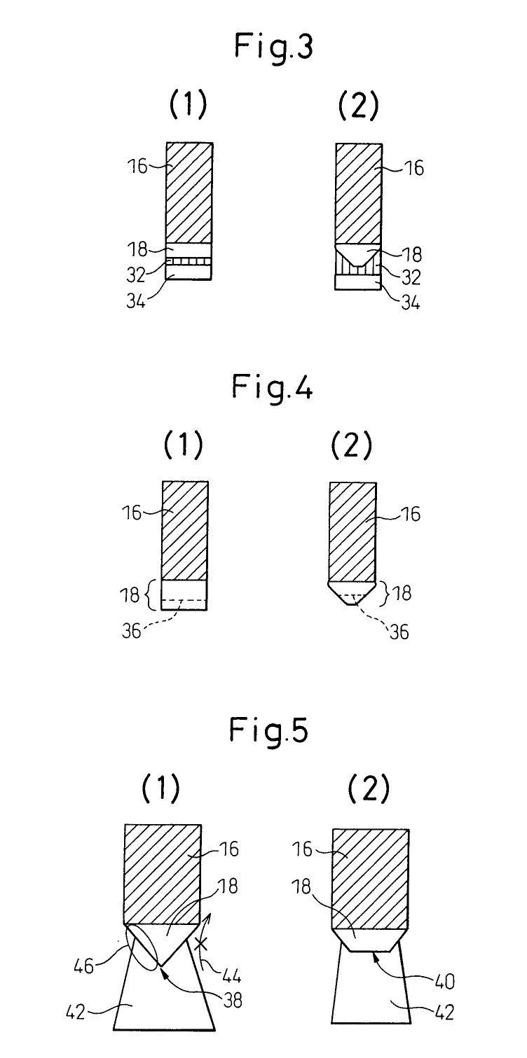

In another mode, as shown in FIGS. 3(1) to (2), it is also possible to make small pieces 34 of SiC, Si, or other materials not having a detrimental effect on the growth even if mixed into the solution adhere to the surface of the seed crystal 18 by a C adhesive or SiO₂ film etc. 32. While it is not possible to ease the heat shock like with the above protective coating 30, it is possible to prevent abnormal growth due to deposition of the vapor of the solution on the surface of the SiC single crystal (formation of polycrystals etc.). Further, the seed touch surface (surface on which small pieces are adhered) and growth surface (seed crystal surface) are separated, so it is possible to avoid the formation of defects at the initial growth layer.

In another mode, as shown in FIGS. 4(1) to (2), it is possible to inject ions 36 into the seed crystal 18. Due to disassociation at the ion injection part 36 due to the temperature rise, the seed touch surface and the growth surface can be separated and the growth surface can be kept cleaner. Further, contamination of the solution by foreign matter can be prevented.

In another embodiment, as shown in FIGS. 5(1) to (2), the tip of the seed crystal (1) may be made a pointed shape (38) or (2) may be made a plateau shape (40). It is therefore possible to minimize the location where defects are formed at the time of seed touch and possible to grow the crystal after adjusting the area of the growth surface by subsequent meltback. The risk of formation of defects is avoided and simultaneously the crystal can be easily increased in size (a SiC single crystal is generally difficult to increase in size). Furthermore, the starting part of growth is a narrowed shape, so there is also the effect of prevention of the solution rising up (44) and wetting the support shaft 16. At the pointed or plateau shaped inclined part 46, the 4H—SiC stacked structure of the seed crystal 18 is exposed. Even with a larger size SiC single crystal 42, a 4H—SiC structure of the same stacked order continued is easily obtained.

### EXAMPLES

The following procedure was used to grow an SiC single crystal.

Basic crystal growth process
Growth preparations (see FIG. 1)

(1) Adhere 4H—SiC seed crystal 18 to graphite support shaft 16.

(2) Charge graphite crucible 10 with feedstock.

(3) Configure these as shown in FIG. 1

(4) Introduce Ar 20 at atmospheric pressure.

(5) Raise temperature to desired level
Seed touch

(1) After temperature of solution 14 reaches sufficient temperature, make support shaft descend.

(2) Make shaft 16 descend until seed crystal 18 touches solution 14 and penetrates it desired depth (*), then make shaft stop. (*: In the present example, make it stop at position where seed crystal 18 touches surface of solution 14. In general, seed crystal 18 sometimes sinks into solution 14.)
Growth

(1) Make solution temperature rise to desired growth temperature.

(2) Hold for any time to grow crystal, then pull up shaft 16.

(3) Cool shaft 16 and solution 14 over several hours.

Below, the specific procedure and conditions for the example of the present invention and comparative examples outside the scope of the present invention will be explained.

### Comparative Example 1

An Si melt was used for growth on a 4H—SiC seed crystal. The seed touch temperature and the growth temperature were both about 1950° C. At this time, it was possible to obtain an SiC single crystal of a thickness of about 100 μm in a growth time of about 1 hour. This crystal was etched by molten KOH. The dislocations at the crystal surface were brought out as etch pits. The density of etch pits was 3×10⁵ cm⁻². This clearly increased over the defect density level of 10³ cm⁻² of the seed crystal.

### Comparative Example 2

The seed touch temperature was made 1900° C. The solution was held until the temperature stabilized, then the seed touch was performed. After that, the temperature was raised to 1950° C. and growth was performed for 1 hour. At this time, a thickness 120 μm or so SiC single crystal could be obtained. This crystal was etched by molten KOH, whereby the density of etch pits was 1×10⁵ cm⁻². This clearly increased over the defect density level of 10³ cm⁻² of the seed crystal.

### Example 1

According to the present invention, the seed touch was performed without a temperature holding operation during the temperature elevation process.

The solution was raised in temperature. When reacting 1900° C., the seed touch was immediately performed with a temperature holding operation. The temperature was raised to 1950° C., then the growth was performed for 1 hour at that temperature. An SiC single crystal of a thickness of about 60 μm could be obtained. This crystal was etched by molten KOH, whereby the density of etch pits was 3×10³ cm⁻². This is similar to the defect density level of 10³ cm⁻² of the seed crystal.

Compared with Comparative Example 2, the thickness of the obtained crystal is a thin one of about 60 μm. Further, despite the seed touch having been performed at the same temperature as Comparative Example 2, the dislocation density is two orders of magnitude smaller. By performing the seed touch in this way in the state of a low C saturation degree of the solution without performing a temperature holding operation at the time of seed touch according to the present invention, it is possible to suppress the formation of a crystal layer including a large number of dislocations at the time of seed touch and possible to realize lower dislocations of the growth layer by meltback in the subsequent saturation process of the solution. The occurrence of meltback is suggested since the obtained SiC single crystal has become thinner.

### Comparative Example 3

A solution of Si in which 10 at % of Cr was added was used for growth. The temperature was raised to the growth temperature 1950° C., then the temperature was held for 30 minutes, then seed touch was performed. The growth was performed for 1 hour. The etch pit density of the obtained SiC single crystal was 9×10⁴ cm⁻².

### Comparative Example 4

A solution of Si in which 30 at % of Cr was added was used for growth in the same way as Comparative Example 3. The etch pit density of the obtained SiC single crystal was 3×10⁵ cm⁻².

### Comparative Example 5

A solution of Si in which 40 at % of Cr was added was used for growth. The temperature was raised to the growth temperature 1950° C., then the temperature was held for 90 minutes, then seed touch was performed. The growth was performed for 1 hour. The etch pit density of the obtained SiC single crystal was 5×10⁵ cm⁻².

### Comparative Example 6

A solution of Si in which 40 at % of Cr was added was used for growth. The temperature was raised to the growth temperature 1950° C., then the temperature was held for 150 minutes, then seed touch was performed. The growth was performed for 1 hour. The etch pit density of the obtained SiC single crystal was 5×10⁵ cm⁻².

### Example 2

A solution of Si in which 40 at % of Cr was added was used for growth. The temperature was raised to the growth temperature 1950° C., then, without holding the temperature according to the present invention, seed touch was performed. The growth was performed for 1 hour. The etch pit density of the obtained SiC single crystal was 7×10⁴ cm⁻².

### Example 3

A solution of Si in which 40 at % of Cr was added was used for growth. The temperature was raised to the growth temperature 1950° C., then the temperature was held for 30 minutes according to the present invention, then seed touch was performed. The growth was performed for 1 hour. The etch pit density of the obtained SiC single crystal was 3×10³ cm⁻².

### Example 4

A solution of Si in which 40 at % of Cr was added was used for growth. The temperature was raised to the growth temperature 1950° C., then the temperature was held for 60 minutes according to the present invention, then seed touch was performed. The growth was performed for 1 hour. The etch pit density of the obtained SiC single crystal was 4×10⁴ cm⁻².

Cr promotes the dissolution of C and causes the growth rate to increase. By adding a metal causing such an increase in the amount of dissolution of C in a certain amount or more (in the above examples, 40 at % or more), it is possible to delay the C saturation of the solution. Due to this, even if the seed touch is performed after holding the temperature at the growth temperature, if the temperature holding operation is kept within a certain time, it is possible to suppress the formation of dislocations at the growth layer and remove the locations where dislocations are formed by meltback in the subsequent saturation process of the solution. Even if using Ti instead of Cr, similar effects are obtained. Further, it is possible to use Al, Fe, Co, Ni, V, Zr, Mo, W, Ce, or another element.

### Example 5

Except for coating the surface of the seed crystal with Cr by vapor deposition, growth was performed under conditions similar to Comparative Example 1. The etch pit density of the obtained SiC single crystal was 7×10⁴ cm⁻². This was reduced to ¼ that of Comparative Example 1.

The results obtained by the above examples and Comparative examples are shown together in Table 1.

TABLE 1

| | | Seed touch | Growth | Holding | | |
|---|---|---|---|---|---|---|
| | | temper- | temper- | time before | | Etch pit |
| | | ature | ature | seed touch | | density |
| Experiments | | (° C.) | (° C.) | (min) | Solvent | (cm⁻²) |
| | Comp. | 1950 | 1950 | >60 | Si | 3 × 10⁵ |
| | Ex. 1 | | | | | |
| A | Comp. | 1900 | 1950 | >60 | Si | 1 × 10⁵ |
| | Ex. 2 | | | | | |
| | Ex. 1 | 1900 | 1950 | 0 | Si | 3 × 10³ |
| B | Comp. | 1950 | 1950 | 30 | Si + 10 | 9 × 10⁴ |
| | Ex. 3 | | | | at % Cr | |
| | Comp. | 1950 | 1950 | 30 | Si + 30 | 3 × 10⁵ |
| | Ex. 4 | | | | at % Cr | |
| | Comp. | 1950 | 1950 | 90 | Si + 40 | 5 × 10⁵ |
| | Ex. 5 | | | | at % Cr | |
| | Comp. | 1950 | 1950 | 150 | Si + 40 | 5 × 10⁵ |
| | Ex. 6 | | | | at % Cr | |
| | Ex. 2 | 1950 | 1950 | 0 | Si + 40 | 7 × 10⁴ |
| | | | | | at % Cr | |
| | Ex. 3 | 1950 | 1950 | 30 | Si + 40 | 3 × 10³ |
| | | | | | at % Cr | |
| | Ex. 4 | 1950 | 1950 | 60 | Si + 40 | 4 × 10⁴ |
| | | | | | at % Cr | |
| | Ex. 5 | 1950 | 1950 | >60 | Si(*) | 7 × 10⁴ |

(*)Surface of seed crystal coated with Cr.

As shown in Table 1, according to the series of experiments A, by performing the seed touch without a temperature holding operation during the temperature elevation process, the etch pit density of the grown crystal was reduced to the same level as the defect density of the seed crystal. This is believed due to the fact that the C saturation degree of the solution at the time of the seed touch fell and formation of crystal at the instant of the seed touch could be prevented and the fact that the seed crystal surface was melted back in the subsequent saturation process of the solution.

Further, according to the series of experiments B, it was learned that by using a solvent promoting the dissolution of C, it is possible to delay the C saturation of the solution and obtain a similar effect as the above.

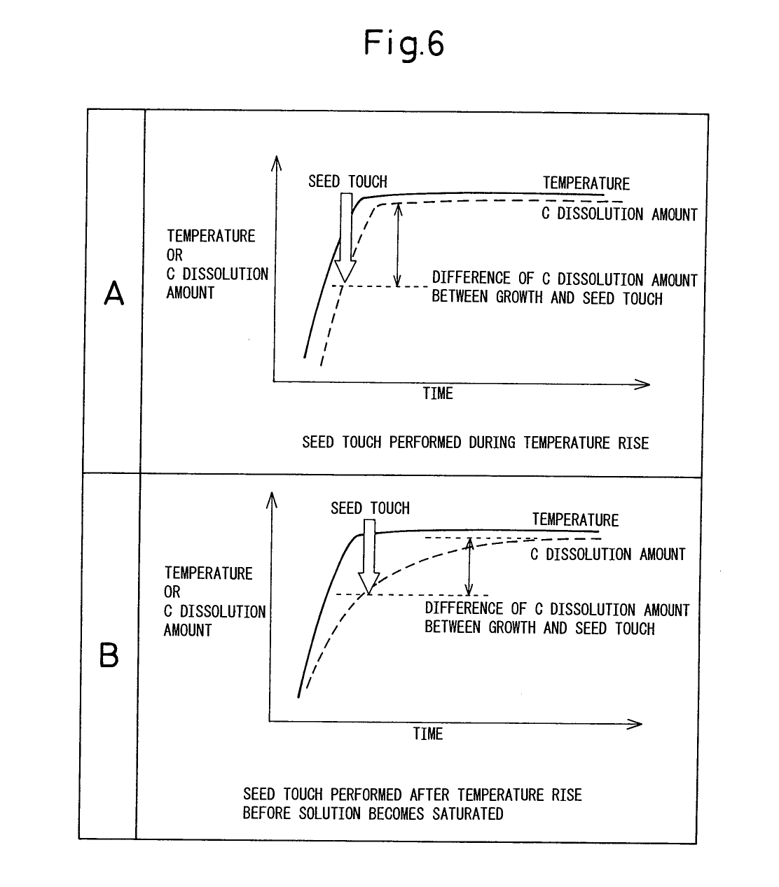

FIG. 6 schematically shows the relationship between the temperature at the time of growth and the amount of dissolution of carbon for the two modes A and B. The modes A and B correspond to the experiments A and B in Table 1.

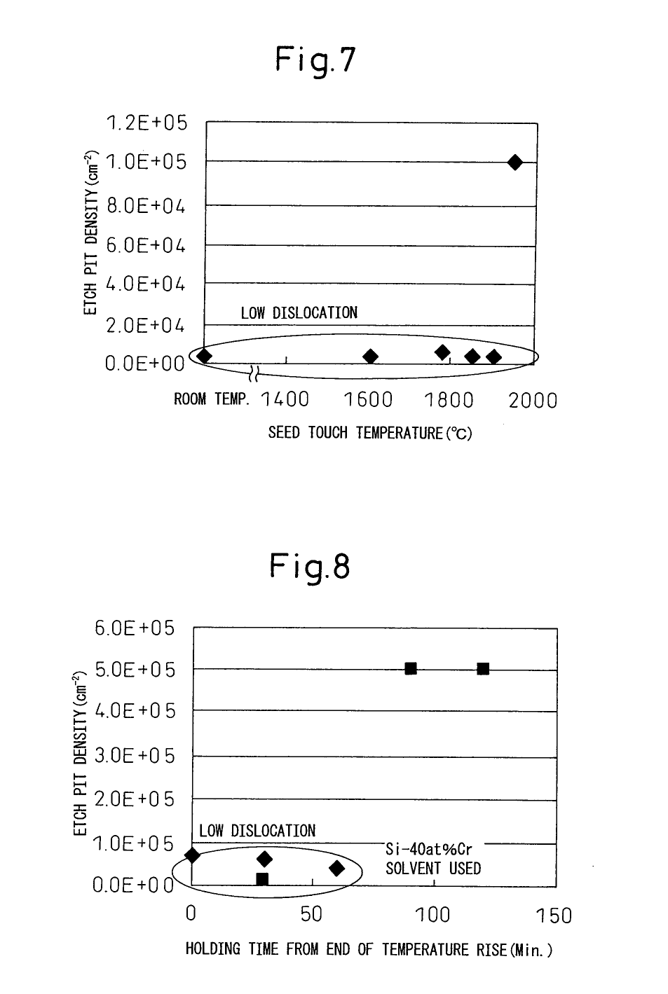

FIG. 7 shows the relationship between the etch pit density of the SiC single crystal (ordinate) and seed touch temperature (abscissa) for the mode A. The results of Example 1 and Comparative Example 2 are plotted together with other data. The seed touch was performed at various temperatures in the middle of the temperature elevation process for a growth temperature of 1950° C. If not holding the temperature at the seed touch the etch pit density is low. This is because the solution is not saturated with C at the time of the seed touch. The plot at the right end shows the case of performing the seed touch at a growth temperature of 1950° C. The increase in amount of dissolution of C is slightly delayed from the temperature elevation process, so the solution already becomes saturated with C at the time of the seed touch. Due to the formation of defects accompanying the seed touch operation, the etch pit density greatly increases.

FIG. 8 shows the relationship between the etch pit density of the SiC single crystal (ordinate) and seed touch temperature (abscissa) for the mode B. The data of Examples 1 to 3 and Comparative Examples 5 and 6 are plotted. 40 at % of Cr was added to the Si, whereby the saturation concentration of C rose and a longer time was taken until reaching C saturation. Even after the growth temperature 1950° C. is reached and temperature elevation is ended, if the holding time is within 60 minutes, it is possible to perform the seed touch before the solution becomes saturated with C and formation of defects due to the seed touch can be de facto prevented.

### INDUSTRIAL APPLICABILITY

According to the present invention, there is provided a method of production of SiC single crystal using the solution method which prevents the formation of defects due to causing seed crystals to touch the melt for seed touch, and thereby causes growth of Si single crystal reduced in defect density.

The present invention can be used for SiC bulk crystal growth and epitaxial growth. A bulk crystal and epitaxial growth layer obtained by these growth methods are also provided.

The present invention further can be used to form a buffer layer between a wafer and an epitaxial growth layer. A buffer layer formed by this is also provided.

The present invention further can be used to form a reduced dislocation layer at the surface of the seed crystal. It is possible to adjust the off angle of this reduced dislocation layer, then perform bulk growth and thereby form a low dislocation bulk crystal.

1. A method of production of an SiC single crystal which causes an SiC seed crystal to touch a melt containing Si in a graphite crucible to thereby cause growth of the SiC single crystal on the SiC seed crystal, characterized by:
making the SiC seed crystal touch the melt in the state where the C is not yet saturated.

2. A method of production of an SiC single crystal as set forth in claim 1, wherein the touch operation is performed at a temperature of the above temperature for causing growth or less and the temperature is not held at the touched state.

3. A method of production of an SiC single crystal as set forth in claim 1, wherein an element for raising the solubility of C in the melt is added in the period from before touch to the start of growth.

4. A method of production of an SiC single crystal as set forth in claim 3, wherein a temperature holding operation is performed for not more than 60 minutes at the temperature for causing growth, then the seed touch operation is performed.
